(19) United States
(12) Patent Application Publication
(10) Pub. No.: US 2007/0279883 A1
(43) Pub. Date: Dec. 6, 2007

(54) Locking device having releasing arm

(75) Inventor: Li-Ching Hung, Gueishan Township (TW)

Correspondence Address: TROXELL LAW OFFICE PLLC, SUITE 1404, 5205 LEESBURG PIKE, FALLS CHURCH, VA, 22041, US

(73) Assignee: SPEED TECH CORP.

(21) Appl. No.: 11/442,634

(22) Filed: May 30, 2006

(51) Int. Cl. H05K 7/14

(52) U.S. Cl. 361/796

(57) ABSTRACT

A locking device has two components. One of the components is adhered to a printed circuit board (PCB) and has two releasing arms penetrated through the PCB. Each releasing arm has a protrusion. The other component has two flanges. The two components are fixed by using the protrusions and the flanges. And the two components are to be released by using the releasing arms. Besides, the material, the producing time and the producing procedures are saved.

### FIELD OF THE INVENTION

The present invention relates to a locking device; more particularly, relates to firmly fixing two components of the locking device accompanying a releasing arm, where the components is to be easily released with the re lea sing arm; and the material, the producing time and the producing procedure are saved as well.

### DESCRIPTION OF THE RELATED ART

A prior art, as shown in FIG. 5 and FIG. 6, is called “An electrical connector assembly”, revealed in U.S. Pat. No. 6,805,571 B2. The prior art comprises a first connector 4 and a second connector 5, where the first connector 4 comprises a first dielectric housing 41, a plurality of first terminals 42 and a latch 43, and the second connector comprises a second dielectric housing 51 and a plurality of second terminals 52. Therein, the plurality of first terminals 42 is received in the first dielectric housing 41; the latch 43 is assembled on the first dielectric housing 41; the first dielectric housing 41 comprises an end wall defining a receiving space 411; the latch 43 comprises a retaining portion 431 and a spring portion 432; the retaining portion 431 is retained in the receiving space 411; the spring portion 432 comprises a pair of spring legs 433 and a locking portion 434; the pair of spring legs 433 extends downwardly from a lower end of the retaining portion 431; the locking portion 434 extends downwardly form each of the spring legs 433; each of the spring legs 433 has a curved section; and the retaining portion 431 and the locking portion 434 are coplanar with each other. The second dielectric housing 51 defines a recess 43 to receive the curved sections of the spring legs 433; the plurality of second terminals 52 receives in the second dielectric housing 51 and electrically connects with the first terminals 42; the receiving space 411 of the first dielectric housing 41 comprises a cutout, an upper indentation and a lower slot; the cutout receives the spring portion 432 of the latch 43 therein; the upper indentation communicates with the cutout and receives the retaining portion 431 of the latch 43 therein; and the lower slot communicates with the cutout and receives the locking portion 434 of the latch 43 therein. Thus, the prior art of “An electrical connector assembly” is constructed and the first and second connectors 4,5 are firmly fixed together.

Although the first and the second connectors 4,5 of the above prior art are firmly fixed, the latch 43 comprises the retaining portion 431, the spring portion 432, the spring legs 433 and the locking portion 434 to construct a complex structure and is hard for fabrication. Secondly, the latch 43 and the first dielectric housing 41 are two separated components so that the latch 43 has to be inserted into the receiving space 411 of the first dielectric housing 41 on assembling. As a result, the producing hour, the producing procedure and the production cost is increased. Besides, because the latch 43 is made of a metal, its elasticity is a metallic elasticity which may make the metal deformed after times of plugging and unplugging. In the end, the spring portion 432 of the latch 43 can no more firmly butted against in the recess 43 of the second connector 5. Hence, the prior art does not fulfill users' requests on actual use.

### SUMMARY OF THE INVENTION

The main purpose of the present invention is to firmly fix a first and a second components of a locking device through a fixing part and a concave part, where the first component has a pair of flexible releasing arms penetrating through at lease one hole of a printed circuit board (PCB); the part of the releasing arm penetrated out of the PCB can be bended to release the first and the second components; and, moreover, the material, the producing time and the producing procedure are saved.

To achieve the above purpose, the present invention is a locking device having a releasing arm, comprising a first component, a PCB and a second component, where the first component is deposed on the PCB; the first component comprises a first insulated body and a plurality of first conducting terminals; the first insulated body has a containing member; the plurality of first conducting terminal protrudes into the containing member; the containing member has a slot at each end; each slot has a fixing part; the fixing part comprises a pair of releasing arms each having a convex part; the PCB has a pair of holes; each releasing arm penetrates out of one of the holes of the PCB; the second component has a second insulated body and a plurality of second conducting terminals; the second insulated body has an inserting member inserted into the containing member so that the plurality of second conducting terminals is located at the inserting member and is connected with the plurality of the first conducting terminals; the inserting member has a positioning part at each end to be inserted into the slot following the inserting of the inserting member into the containing member; the positioning part has a concave part to be fixed with the convex part so that the first component and the second component are fixed together; and the concave part and the convex part is to be departed by bending the part of the releasing arm penetrated out of the hole of the PCB so that the first component and the second component are released. Accordingly, a novel locking device having are easing arm is obtained.

### BRIEF DESCRIPTIONS OF THE DRAWINGS

The present invention will be better understood from the following detailed description of the preferred embodiment according to the present invention, taken in conjunction with the accompanying drawings, in which

FIG. 1 is a view showing the assembling of the preferred embodiment according to the present invention;

FIG. 2 is a perspective view showing the first component and the PCB;

FIG. 3 is a perspective view showing the second component;

FIG. 4 is a sectional view showing the assembly of the preferred embodiment;

FIG. 5 is a view of the assembling of the prior art; and

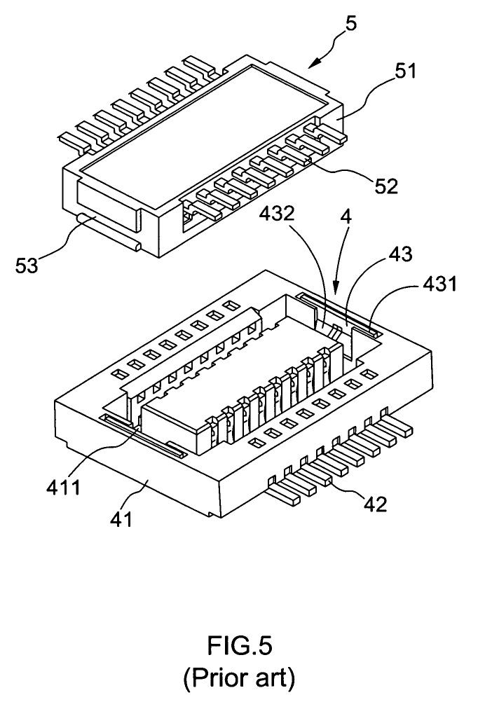

FIG. 6 is a view of the locking part of the prior art.

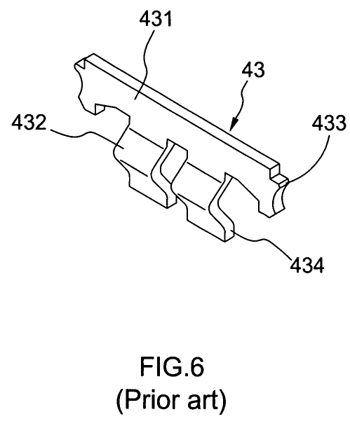

### DESCRIPTION OF THE PREFERRED EMBODIMENT

The following description of the preferred embodiment is provided to understand the features and the structures of the present invention.

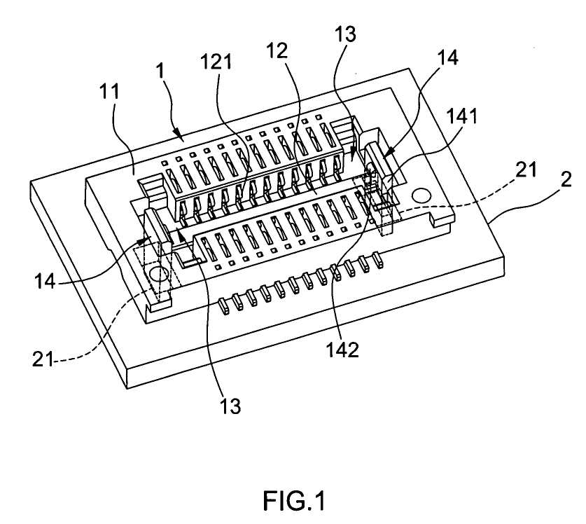

Please refer to FIG. 1, which is a view showing the assembling of the preferred embodiment according to the present invention. As shown in the figure, the present invention is a locking device having a releasing arm, comprising a first component 1, a printed circuit board (PCB) 2 and a second component 3, where the first component 1 is deposed on the PCB 2; and the first and the second components 1,2 are fixed together.

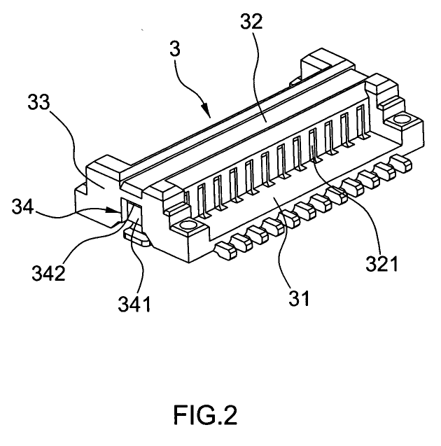

Please refer to FIG. 2, which is a perspective view showing the first component and the PCB. As shown in the figure, the first component 1 comprises a first insulated body 11 and a plurality of first conducting terminals 121, where the first insulated body 11 has a containing member 12; at least one first conducting terminal 121 is protruded into the containing member 12; the containing member 12 has a pair of slots 13 at two opposite ends of the containing member; each slot 13 has a fixing part 14; the pair of fixing parts 14 has a pair of releasing arms 141 extended vertically from and unitized with the pair of slots 13 separately; the releasing arms 141 penetrates out of the PCB 2; and the releasing arm 141 has a convex part 142 on a surface corresponding to the containing member 12. The PCB 2 has a pair of holes 21; and the first component 1 is deposed on the PCB 2. The pair of releasing arms 141 of the fixing parts 14 penetrate out of the pair of holes 21 separately.

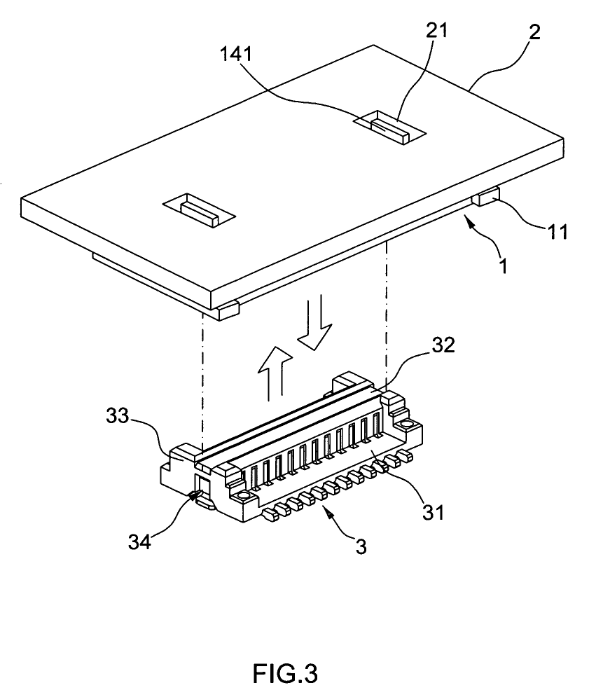

Please refer to FIG. 3, which is a perspective view showing the second component. As shown in the figure, the second component 3 comprises a second insulated body 31 and a plurality of second conducting terminals 321, where the second insulated body 31 has an inserting member 32; the inserting member 32 is inserted into the containing member 12 the plurality of second conducting terminals 321 is connected with the plurality of first conducting terminals 121; the inserting member 32 has a pair of positioning parts 33 corresponding to the pair of slots 13 separately; each positioning part 33 has a concave part 34 on a surface corresponding to the fixing part 14; the concave part 34 comprises a locking space 341 and a flange 342; and the flange 342 is at an end of the locking space 341.

Thus, a novel locking device having a releasing arm is obtained.

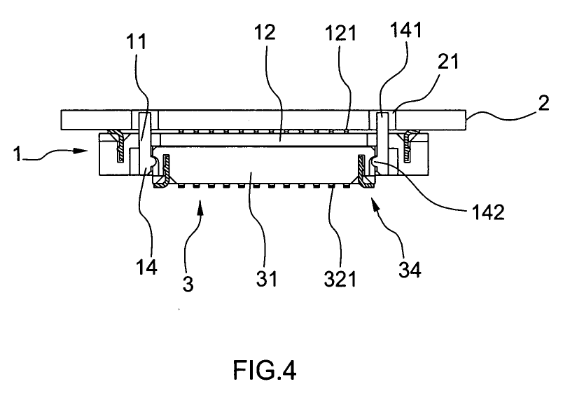

Please refer to FIG. 1 and FIG. 4, which are a view showing the assembling and a sectional view showing the assembly of the preferred embodiment. As shown in the figures, when assembling the present invention, an inserting member 32 of a second component 3 is correspondingly inserted into a containing member 12 of the first component 1 so that the positioning part 33 is inserted into the slot 13. Therein, the flange 342 of the concave part 34 is pushed against the convex part 142 of the fixing part 14; then the releasing arm 141 is pushed by the convex part 142 to be moved a side a little to pass the convex part 142 through the flange 342 of the concave part 34; after the convex part 142 is passed through the flange 342, the releasing arm 141 is returned to the original status to position the convex part 142 in the locking space 341 and to butt the convex part 142 against the flange 342. In this way, the flange 342 is firmly fixed with the convex part 142.

Besides, the first component 1 is deposed on the PCB; and the releasing arms 141 of the fixing parts 14 are separately corresponding to the holes 21 of the PCB. The releasing arms 141 corresponding to the holes 21 are moved inwardly to correspondingly move the convex parts 142 on the releasing arms 141 so that the convex parts 142 are moved out of the flange 342 of the concave part 34 to release the second component 3 from the first component 1.

To sum up, the present invention is a locking device having a releasing arm, where components of a locking device is firmly fixed with a concave part and a convex part; components of a locking device is to be easily released by using a releasing arm and the material, the producing time and the producing procedure are saved.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A locking device having a releasing arm, comprising:
a first component, said first component comprising
a first insulated body, said first insulated body having a containing member, said containing member having a pair of slots, each said slot having a fixing part, each fixing part having a releasing arm, said releasing arm having a convex part on a surface of said releasing arm; and
a plurality of first conducting terminals;
a printed circuit board (PCB), said PCB having a pair of holes; and
a second component, said second component comprising
a second insulated body, said second insulated body having an inserting member, said inserting member having a pair of positioning parts; each said positioning part having a concave part; and
a plurality of second conducting terminals,
wherein said convex part is corresponding to said concave part;
wherein said pair of slots is separately located at two opposite ends of said containing member;
wherein said plurality of second conducting terminals is located at said inserting member;
wherein a part of said first conducting terminal is protruded into said containing member and is connected with said second conducting terminal;
wherein said first component is deposed on said PCB;
wherein each said releasing arm is extended from a bottom of said slot and is unitized with said slot;
wherein said pair of releasing arms separately penetrates through said pair of holes correspondingly;
wherein said inserting member is inserted into said containing member;
wherein said pair of positioning parts is separately located at two opposite ends of said inserting member and is separately inserted into said pair of slots; and
wherein said first component and said second component are fixed tog ether by using said concave parts of said positioning parts and said convex parts of said releasing arms.

2. The locking device according to claim 1,
wherein said concave part is located on a surface of said positioning part corresponding to said releasing arm;
wherein said concave part comprises a locking space and a flange; and
wherein said flange is located at an end of said concave part.
